(19) United States
(12) Patent Application Publication
(10) Pub. No.: US 2013/0095643 A1
(43) Pub. Date: Apr. 18, 2013

(54) METHODS FOR IMPLANTING DOPANT SPECIES IN A SUBSTRATE

(71) Applicants: KARTIK SANTHANAM, Malta, NY (US); MATTHEW D. SCOTNEY-CASTLE, Morgan Hill, CA (US); MANOJ VELLAIKAL, Sunnyvale, CA (US); PETER I. PORSHNEV, Poway, CA (US)

(72) Inventors: KARTIK SANTHANAM, Malta, NY (US); MATTHEW D. SCOTNEY-CASTLE, Morgan Hill, CA (US); MANOJ VELLAIKAL, Sunnyvale, CA (US); PETER I. PORSHNEV, Poway, CA (US)

(73) Assignee: APPLIED MATERIALS, INC., Santa Clara, CA (US)

(21) Appl. No.: 13/274,776

(22) Filed: Oct. 17, 2011

(51) Int. Cl. H01L 21/265

(52) U.S. Cl. 438/514; 257/E21.334

(57) ABSTRACT

Methods for processing a substrate are provided herein. In some embodiments, a method of processing a substrate may include implanting a dopant species into the one or more regions of the substrate using a first dopant precursor comprising a hydride of the dopant species; and implanting the dopant species into the one or more regions of the substrate using a second dopant precursor comprising fluorine and the dopant species. In some embodiments, the first and second dopant precursors may be provided simultaneously. In some embodiments, the first dopant precursor may be provided for a first time period, followed by providing the first dopant precursor and the second dopant precursor for a second period of time. In some embodiments, the flow of the first dopant precursor and the flow of the second dopant precursor may be alternated until a desired implant level is reached.

### FIELD

Embodiments of the present invention generally relate to semiconductor manufacturing.

### BACKGROUND

Dopant precursors used in doping processes in the semiconductor industry may include either fluorine-based precursors (such as boron trifluoride) or hydride-based precursors (such as diborane or phosphine). However, the inventors have observed that plasma doping processes using either of these dopant precursors have undesirable side effects.

Accordingly, the inventors have provided methods of doping substrates.

### SUMMARY

Methods for processing a substrate are provided herein. In some embodiments, a method of processing a substrate may include implanting a dopant species into the one or more regions of the substrate using a first dopant precursor comprising a hydride of the dopant species; and implanting the dopant species into the one or more regions of the substrate using a second dopant precursor comprising fluorine and the dopant species.

In some embodiments, the method of processing a substrate may include simultaneously providing the first and second dopant precursors to implant the dopant species. In some embodiments, the method of processing a substrate may include flowing the first dopant precursor for a first time period; and co-flowing the first dopant precursor and the second dopant precursor for a second period of time following the first period of time. In some embodiments, the method of processing a substrate may include alternating the flow of the first dopant precursor and the flow of the second dopant precursor until a desired implant level is reached.

In some embodiments, the invention may be embodied on a computer readable medium having instructions stored thereon that, when executed by a processor, cause a process chamber to perform a method for processing a substrate in accordance with any of the embodiments described herein.

Other and further embodiments of the present invention are described below.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a flow chart for a method of processing a substrate in accordance with some embodiments of the present invention.

FIG. 2 depicts a flow chart for a method of processing a substrate in accordance with some embodiments of the present invention.

FIG. 3 depicts a flow chart for a method of processing a substrate in accordance with some embodiments of the present invention.

FIG. 4 depicts a plasma immersion ion implantation process chamber in accordance with some embodiments of the present invention.

To facilitate understanding, identical reference numerals have been used, where possible, to designate identical elements that are common to the figures. The above drawings are not to scale and may be simplified for illustrative purposes.

### DETAILED DESCRIPTION

Embodiments of the present invention provide improved methods for implanting dopant species in a substrate. Embodiments of the present invention may advantageously reduce wafer non-uniformity caused by plasma doping with either of fluorine precursors or hydride precursors. Exemplary, but non-limiting, examples of target areas for the inventive methods disclosed herein may include polydoping, ultra shallow junction (USJ), source drain regions, and conformal doping applications.

In some embodiments, the substrate to be doped may comprise any suitable material or materials used in the fabrication of semiconductor devices. For example, in some embodiments, the substrate may comprise a semiconducting material and/or combinations of semiconducting materials and non-semiconducting materials for forming semiconductor structures and/or devices. The substrate may further comprise multiple layers. For example, the substrate may comprise one or more silicon-containing materials such as crystalline silicon (e.g., Si<100> or Si<111>), silicon oxide, strained silicon, polysilicon, silicon wafers, glass, sapphire, or the like. The substrate may further have any desired geometry, such as a 200 or 300 mm wafer, square or rectangular panels, or the like. In some embodiments, the substrate may be a semiconductor wafer (e.g., a 200 mm, 300 mm, or the like silicon wafer).

When doping the substrate, the entire surface of the substrate may be doped, or if select regions of the substrate are to be doped, a patterned mask layer, such as a patterned photoresist layer, may be deposited atop the substrate to protect regions of the substrate that are not to be doped. For example, in some embodiments, a masking layer, such as a layer of photoresist, may be provided and patterned such that the doped region is formed only on portions of the substrate.

The dopant species may comprise any suitable element or elements typically used in semiconductor doping processes. Examples of suitable dopants include one or more of group III elements or group V elements, such as, in a non-limiting example, arsenic (As), boron (B), indium (In), phosphorous (P), antimony (Sb), or the like. Examples of n-type dopant species may include at least one of phosphorus, arsenic, or the like. Examples of p-type doping species include boron.

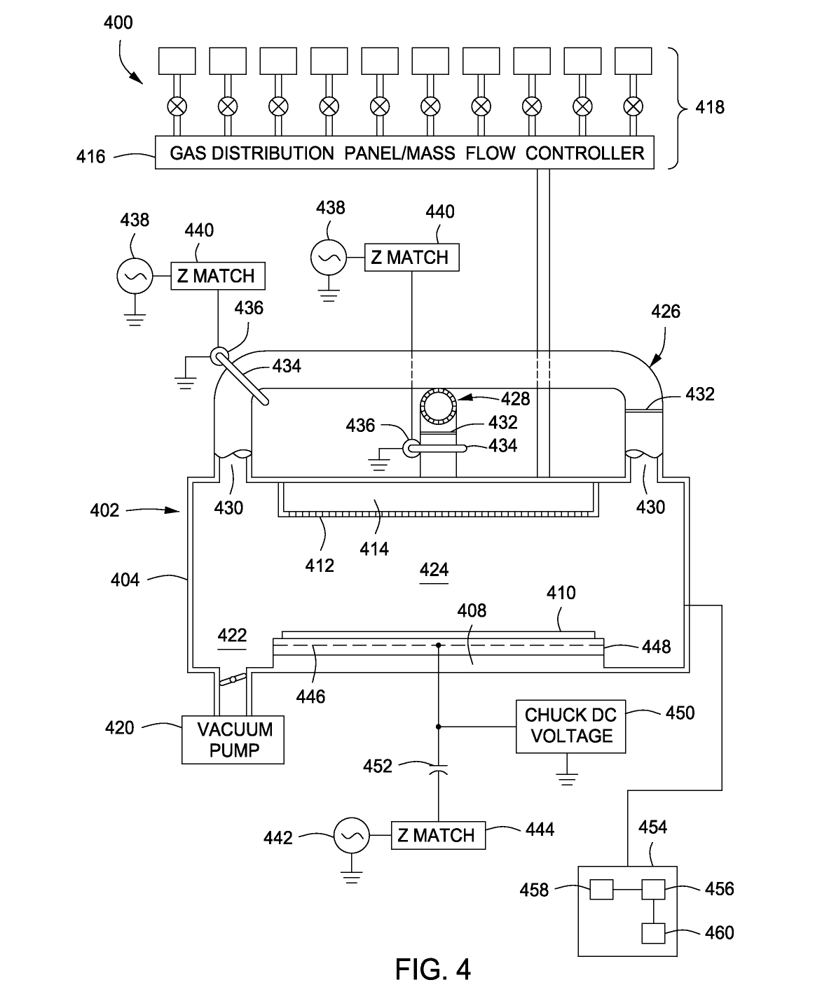

The doped region may be formed by implanting one or more dopants into the substrate in an implantation process, such as a plasma assisted implantation process. The doping process may be performed in any suitable doping chamber, such as a plasma-assisted doping chamber. For example, embodiments of the present invention may be performed in toroidal source plasma ion immersion implantation reactor such as, but not limited to, the CONFORMA™ reactor commercially available from Applied Materials, Inc., of Santa Clara, Calif. Such a suitable reactor and its method of operation are set forth in U.S. Pat. No. 7,166,524. Other implantation reactors may also be used. An exemplary toroidal source plasma ion immersion implantation reactor suitable for carrying out embodiments of the present invention is described below with respect to FIG. 4.

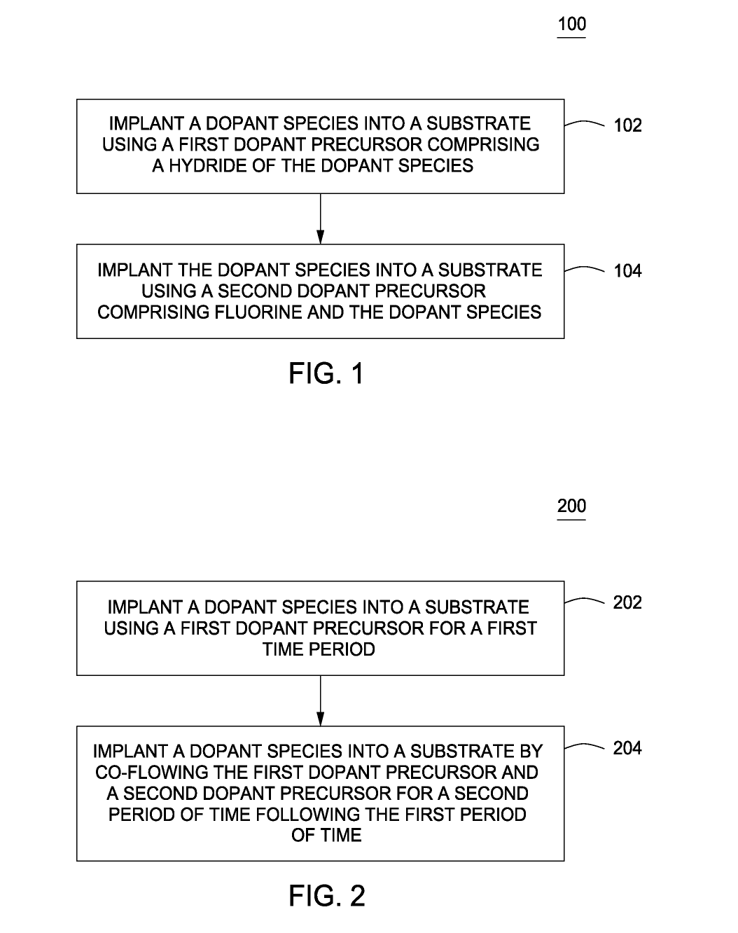

FIG. 1 depicts a method 100 for processing a substrate in accordance with some embodiments of the present invention. The method 100 generally begins at 102, where a dopant species is implanted into one or more regions of a substrate (including the entire substrate) using a first dopant precursor comprising a hydride of the dopant species (e.g., a hydride dopant precursor). For example arsine (AsH₃) or phosphine (PH₃) are a typical hydride dopant precursors used for n-type implant process targeting conformal FINFET (FIN Field Effect Transistors), conformal DRAM (Dynamic Random Access Memory) and conformal Flash doping applications. For p-type doping applications, hydride dopant precursors such as diborane (B₂H₆) may be used.

At 104, the dopant species is implanted into the one or more regions of the substrate using a second dopant precursor comprising fluorine and the dopant species (e.g., a fluorine-based dopant precursor). Examples of suitable fluorine-based dopant precursors include boron trifluoride (BF₃).

The inventors have observed that implantation processes using hydride dopant precursors may result in the deposition of a film on the substrate. Left alone, the film may undesirably cause process non-uniformities. However, the inventors have also observed that implantation processes using fluorine-based dopant precursors may result in etching of the substrate. Left alone, such etching may undesirably cause process non-uniformities. The inventors have discovered that by balancing the deposition effect of the hydride dopant precursor and the etch effect of the fluorine-based dopant precursor yields a process with controlled net deposition and/or etching of the substrate, minimizing any process non-uniformities that might otherwise arise from continued deposition or etching of the substrate.

In some embodiments, the first and second dopant precursors may be simultaneously flowed to the doping chamber. The flow rates and duration of exposure of the substrate to the first and second dopant precursors may vary dependent upon the size of the substrate (and/or regions to be doped) and the particular application (e.g., the desired concentration of dopant to be implanted into the one or more regions of the substrate). Alternatively, the first and second dopant precursors may be alternately flowed to the doping chamber. In such embodiments, either dopant precursor may be provided first and either dopant precursor may be provided last.

Other variations of the flow of the first and second dopant precursors may also be used. For example, FIG. 2 depicts a method 200 for processing a substrate in accordance with some embodiments of the present invention. The method 200 begins at 202 by implanting a dopant species into one or more regions of a substrate using a first dopant precursor comprising a hydride of the dopant species for a first time period. The hydride-based dopant deposition process may advantageously deposit a protective coating on the substrate to protect from subsequent etching when performing a fluorine-based dopant deposition process. The first dopant precursor may be any of the hydride dopant precursors discussed above. In some embodiments the first time period may be about 10 to about 100 seconds.

Next, at 204, the dopant species is implanted into the substrate by co-flowing the first dopant precursor and a second dopant precursor comprising fluorine and the dopant species for a second period of time, following the first period of time. The second dopant precursor may be any of the fluorine-based dopant precursors discussed above. In some embodiments, the second period of time may be about 10 to about 100 seconds.

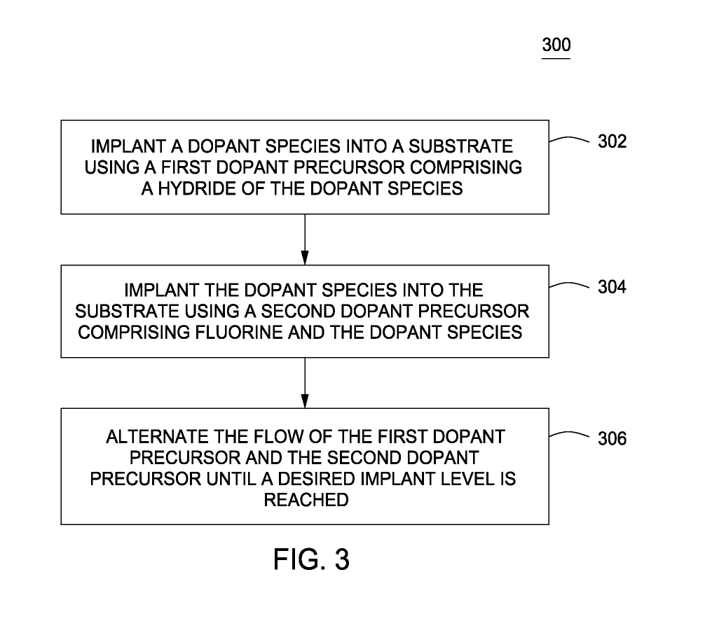

FIG. 3 depicts a method 300 for processing a substrate in accordance with some embodiments of the present invention. The method 300 generally begins at 302, where a dopant species is implanted into one or more regions of a substrate using a first dopant precursor comprising a hydride of the dopant species. At 304, the dopant species is implanted into the one or more regions the substrate using a second dopant precursor comprising fluorine and the dopant species. Next, as depicted at 306, the flows of the first dopant precursor and the second dopant precursor are alternated until a desired implant level is reached. In some embodiments, the desired implant level is about 1E13 to about 1E16 atomic percent of the dopant species.

The above recited method steps may also be reversed—flowing the second dopant precursor first and following with the first dopant precursor. In addition, the number of alternating implant steps need not need be even, e.g., the method can begin and end with the same dopant precursor (which may be either the first dopant precursor or the second dopant precursor).

In some embodiments, the dopant species comprises at least one of boron, phosphorus, arsenic, or carbon. In some embodiments, the first dopant precursor comprises a hydride of the dopant species. In some embodiments, the first dopant precursor includes at least one of diborane (B₂H₆), phosphine (PH₃), arsine (AsH₃), or methane (CH₄). In some embodiments, the second dopant precursor comprises fluorine and the dopant species. In some embodiments, the second dopant precursor includes boron trifluoride (BF₃), phosphorus trifluoride (PF₃), carbon tetrafluoride (CF₄), or di-arsenic trifluoride (AsF₃).

In some embodiments, the depositional nature of the first dopant precursor balances the etching properties of the second dopant precursor, thereby preventing wafer non-uniformity. In some embodiments, the first dopant precursor is diborane (B₂H₆) and the second dopant precursor is boron trifluoride (BF₃). In some embodiments, the first dopant precursor is arsine (AsH₃) and the second dopant precursor is di-arsenic trifluoride (AsF₃). In some embodiments, the first dopant precursor is methane (CH₄) and the second dopant precursor is carbon tetrafluoride (CF₄). In some embodiments, the first dopant precursor is phosphine (PH₃) and the second dopant precursor is phosphorus trifluoride (PF₃).

Referring to FIG. 4, a toroidal source plasma immersion ion implantation reactor 400 of the type disclosed in the above-reference application has a cylindrical vacuum chamber 402 defined by a cylindrical side wall 404 and a disk-shaped ceiling. A substrate support pedestal 408 at the floor of the chamber supports a substrate 410 (e.g., substrate 200) to be processed. A gas distribution plate or showerhead 412 on the ceiling receives process gas in its gas manifold 414 from a gas distribution panel 416 whose gas output can be any one of or mixtures of gases from one or more individual gas supplies 418. A vacuum pump 420 is coupled to a pumping annulus 422 defined between the substrate support pedestal 408 and the sidewall 404. A processing region 424 is defined between the substrate 410 and the gas distribution plate 412.

Pair of external reentrant conduits 426, 428 establishes reentrant toroidal paths for plasma currents passing through the processing region 424, the toroidal paths intersecting in the processing region 424. Each of the conduits 426, 428 has a pair of ends 430 coupled to opposite sides of the chamber. Each conduit 426, 428 is a hollow conductive tube. Each conduit 426, 428 has a D.C. insulation ring 432 preventing the formation of a closed loop conductive path between the two ends of the conduit.

An annular portion of each conduit 426, 428, is surrounded by an annular magnetic core 434. An excitation coil 436 surrounding the core 434 is coupled to an RF power source 438 through an impedance match device 440. The two RF power sources 438 coupled to respective ones of the cores 436 may be of two slightly different frequencies. The RF power coupled from the RF power generators 538 produces plasma ion currents in closed toroidal paths extending through the respective conduit 426, 428 and through the processing region 424. These ion currents oscillate at the frequency of the respective RF power source 438. Bias power is applied to the substrate support pedestal 508 by an RF bias power generator 442 through an impedance match circuit 444.

Plasma formation is performed by introducing a process gas, or mixture of process gases into the chamber 424 through the gas distribution plate 412 and applying sufficient source power from the RF power sources 438 to the reentrant conduits 426, 428 to create toroidal plasma currents in the conduits and in the processing region 424. The plasma flux proximate the wafer surface is determined by the wafer bias voltage applied by the RF bias power generator 442. The plasma rate or flux (number of ions sampling the wafer surface per square cm per second) is determined by the plasma density, which is controlled by the level of RF power applied by the RF power sources 438. The cumulative ion dose (ions/square cm) at the wafer 410 is determined by both the flux and the total time over which the flux is maintained.

If the wafer support pedestal 408 is an electrostatic chuck, then a buried electrode 446 is provided within an insulating plate 448 of the wafer support pedestal, and the buried electrode 446 is coupled to a user-controllable D.C. chucking voltage supply 450 and to the RF bias power generator 442 through the impedance match circuit 444 and through an optional isolation capacitor 452 (which may be included in the impedance match circuit 444).

In operation, and for example, the substrate 410 may be placed on the substrate support pedestal 408 and one or more process gases may be introduced into the chamber 402 to strike a plasma from the process gases.

In operation, a plasma may be generated from the process gases within the reactor 400 to selectively modify surfaces of the substrate 410 as discussed above. The plasma is formed in the processing region 424 by applying sufficient source power from the RF power sources 438 to the reentrant conduits 426, 428 to create plasma ion currents in the conduits 426, 428 and in the processing region 424 in accordance with the process described above. In some embodiments, the wafer bias voltage delivered by the RF bias power generator 442 can be adjusted to control the flux of ions to the wafer surface, and possibly one or more of the thickness a layer formed on the wafer or the concentration of plasma species embedded in the wafer surface. In some embodiments, no bias power is applied.

A controller 454 comprises a central processing unit (CPU) 456, a memory 458, and support circuits 460 for the CPU 456 and facilitates control of the components of the chamber 402 and, as such, of the etch process, as discussed below in further detail. To facilitate control of the process chamber 402, for example as described below, the controller 454 may be one of any form of general-purpose computer processor that can be used in an industrial setting for controlling various chambers and sub-processors. The memory 458, or computer-readable medium, of the CPU 1456 may be one or more of readily available memory such as random access memory (RAM), read only memory (ROM), floppy disk, hard disk, or any other form of digital storage, local or remote. The support circuits 460 are coupled to the CPU 456 for supporting the processor in a conventional manner. These circuits include cache, power supplies, clock circuits, input/output circuitry and subsystems, and the like. The inventive methods, or at least portions thereof, described herein may be stored in the memory 458 as a software routine. The software routine may also be stored and/or executed by a second CPU (not shown) that is remotely located from the hardware being controlled by the CPU 456.

Thus, methods for processing a substrate are provided herein. While the foregoing is directed to embodiments of the present invention, other and further embodiments of the invention may be devised without departing from the basic scope thereof.

1. A method of processing a substrate having one or more regions to be doped, comprising:
implanting a dopant species into the one or more regions of the substrate using a first dopant precursor comprising a hydride of the dopant species; and
implanting the dopant species into the one or more regions of the substrate using a second dopant precursor comprising fluorine and the dopant species.

2. The method of claim 1, wherein the first and second dopant precursors are provided simultaneously.

3. The method of claim 1, further comprising:
flowing the first dopant precursor for a first time period; and
co-flowing the first dopant precursor and the second dopant precursor for a second period of time following the first period of time.

4. The method of claim 3, wherein the first period of time is about 10 to about 100 seconds.

5. The method of claim 3, wherein the second period of time is about 10 to about 100 seconds.

6. The method of claim 1, further comprising:
alternating the flow of the first dopant precursor and the flow of the second dopant precursor until a desired implant level is reached.

7. The method of claim 6, wherein the desired implant level is about 1E13 to about 1E16 atomic percent of the dopant species.

8. The method of claim 1, wherein the dopant species comprises at least one of boron, phosphorous, arsenic, or carbon.

9. The method of claim 8, wherein the first dopant precursor comprises at least one of B₂H₆, PH₃, AsH₃, or CH₄.

10. The method of claim 9, wherein the second dopant precursor comprises a corresponding at least one of BF₃, PF₃, AsF₃, or CF₄.

11. A method of processing a substrate having one or more regions to be doped, comprising:
implanting a dopant species comprising at least one of boron, phosphorous, arsenic, or carbon into the one or more regions of the substrate using a first dopant precursor comprising at least one of B₂H₆, PH₃, AsH₃, or CH₄; and
implanting the dopant species into the one or more regions of the substrate using a second dopant precursor comprising a corresponding at least one of BF₃, PF₃, AsF₃, or CF₄.

12. A computer readable medium having instructions stored thereon that, when executed cause a substrate processing system to perform a method, the method comprising:
implanting a dopant species into the one or more regions of the substrate using a first dopant precursor comprising a hydride of the dopant species; and
implanting the dopant species into the one or more regions of the substrate using a second dopant precursor comprising fluorine and the dopant species.

13. The computer readable medium of claim 12, wherein the instructions further cause the first and second dopant precursors to be provided simultaneously.

14. The computer readable medium of claim 12, wherein the embodied method further comprises:
flowing the first dopant precursors for a first time period; and
co-flowing the first dopant precursor and the second dopant precursor for a second period of time following the first period of time.

15. The computer readable medium of claim 14, wherein the first period of time is about 10 to about 100 seconds.

16. The computer readable medium of claim 14, wherein the second period of time is about 10 to about 100 seconds.

17. The computer readable medium of claim 12, further comprising:
alternating the flow of the first dopant precursor and the flow of the second dopant precursor until a desired implant level is reached.

18. The computer readable medium of claim 17, wherein the desired implant level is about 1E13 to about 1E16 atomic percent of the dopant species.

19. The computer readable medium of claim 12, wherein the first dopant precursor comprises at least one of B₂H₆, PH₃, AsH₃, or CH₄.

20. The computer readable medium of claim 19, wherein the second dopant precursor comprises a corresponding at least one of BF₃, PF₃, AsF₃, or CF₄.
